(19) United States
(12) Patent Application Publication
(10) Pub. No.: US 2024/0213428 A1
(43) Pub. Date: Jun. 27, 2024

(54) LIGHT-EMITTING DEVICE

(71) Applicant: NICHIA CORPORATION, Anan-shi (JP)

(72) Inventor: Norihiro SUGIMOTO, Komatsushima-shi (JP)

(73) Assignee: NICHIA CORPORATION, Anan-shi (JP)

(21) Appl. No.: 18/390,765

(22) Filed: Dec. 20, 2023

(30) Foreign Application Priority Data
Dec. 22, 2022 (JP) 2022-205257

(51) Int. Cl. H01L 33/62; H01L 33/58

(52) U.S. Cl. CPC H01L 33/62; H01L 33/58

(57) ABSTRACT

A light-emitting device includes a light-emitting element; a base member having a first surface where the light-emitting element is disposed, a second surface opposite to the first surface, a lateral wall; a light-transmissive member disposed over the base member to cover the first surface; and a bonding member between a lower surface of the light-transmissive member and an upper surface of the lateral wall, the base member having a first electrode portion, a second electrode portion spaced apart from the first electrode portion, and electrode distinguishing marks respectively provided in vicinities of two adjacent angles of the rectangular outer shape on the upper surface, a portion of the light-transmissive member overlapping with at least a portion of each of the two electrode distinguishing marks in the top view, and the bonding member not disposed at least in the vicinities of the two adjacent angles on the upper surface.

### CROSS-REFERENCE TO RELATED APPLICATIONS

This application claims priority to Japanese Patent Application No. 2022-205257, filed on Dec. 22, 2022, the disclosure of which is hereby incorporated herein by reference in its entirety.

### BACKGROUND

The present invention relates to a light-emitting device.

Japanese Unexamined Patent Application Publication No. 2017-11257 discloses a light-emitting device including a light-emitting element, a substrate having an upper surface on which the light-emitting element is disposed and a lateral wall disposed up to a position higher than the position of the upper surface, and a light-transmissive sealing member bonded to an upper surface of the lateral wall. In the light-emitting device according to Japanese Unexamined Patent Application Publication No. 2017-11257, a distinguishing mark is formed on the upper surface of the lateral wall.

### SUMMARY

In a light-emitting device in which a light-transmissive member is bonded to an upper surface of a lateral wall of a substrate, there is still room for improvement in order to facilitate recognition of a distinguishing mark.

A light-emitting device disclosed in an embodiment includes a light-emitting element; a base member having a rectangular outer shape in a top view and having a first surface, wherein the light-emitting element is disposed at the first surface, a second surface opposite to the first surface, a lateral wall defining a frame surrounding the first surface in the top view, and an upper surface of the lateral wall; a light-transmissive member disposed over the base member to cover the first surface in the top view; and a bonding member disposed between a lower surface of the light-transmissive member and the upper surface to bond the base member and the light-transmissive member together. The base member has a first electrode portion on the second surface, a second electrode portion spaced apart from the first electrode portion, and electrode distinguishing marks respectively provided in vicinities of two adjacent angles of the rectangular outer shape on the upper surface. A portion of the light-transmissive member overlaps with at least a portion of each of the two electrode distinguishing marks in the top view. The bonding member is not disposed at least in the vicinities of the two adjacent angles on the upper surface.

At least one of one or more inventions disclosed according to embodiments provides a light-emitting device with distinguishing marks that are easy to recognize.

### BRIEF DESCRIPTION OF THE DRAWINGS

FIG. 1 is a schematic perspective view of a light-emitting device 1A according to an embodiment.

FIG. 2 is a schematic perspective view of a light-emitting device 1B according to the embodiment.

FIG. 3 is a schematic perspective view of a light-emitting device 1 according to the embodiment before a light-transmissive member 70 is mounted.

FIG. 4 is a schematic top view showing the state shown in FIG. 3.

FIG. 5A is a schematic top view of a base member 10 according to the embodiment.

FIG. 5B is a schematic bottom view of the base member 10 according to the embodiment.

FIG. 6 is a schematic cross-sectional view illustrating an example of a light-emitting element 20 according to the embodiment.

FIG. 7 is a schematic top view of the light-emitting device 1A according to the embodiment.

FIG. 8 is a schematic top view of the light-emitting device 1B according to the embodiment.

### DETAILED DESCRIPTION

In the present specification or the claims, as for polygonal shapes such as triangular shapes and quadrangular shapes, polygonal shapes with rounded corners, beveled corners, angled corners, reverse-rounded corners are also referred to as polygonal shapes. Likewise, not only shapes with such modification at corners (end of sides) but also shapes with modifications at intermediate portions of sides of the shapes are also referred to as polygons. That is, shapes based on polygonal shapes and partially modified are also interpreted as “polygonal shapes” in the present specification and the claims.

Such interpretation is not only polygonal shapes but also applies to terms denoting specific shapes such as trapezoids, circles, protrusions, and recesses. The same applies to sides forming such shapes. That is, even if an end or an intermediate portion of a side is modified, the modified portion is interpreted as a portion of a “side.” When “polygonal shapes” and “sides” without such modified portions are intended to be distinguished from those with modifications, the term “exact” is added, such as an “exact quadrangular shape.”

In the present specification or the claims, expressions such as upper/lower (above/below), right/left, front/back, front/rear (forward/backward), and toward/away merely indicate relative relationships such as relative positions, orientations, and directions and do not have to coincide with relationships during use.

In the present specification or the claims, when there are a plurality of components that are to be distinguished from each other, these components may be described using terms “first” and “second” may be used at the top of the name of the components. Also, there may be a case in which objects to be distinguished differ between the present specification and the claims. Therefore, even if a component described in the claims is indicated by the same term as that in the present specification, the object specified by the component may differ between the present specification and the claims.

For example, in the case in which components are distinguished by the ordinal numbers “first,” “second,” and “third” in the present specification and only the “first” and “third” components in the present specification are described in the claims, these components may be designated using the ordinal numbers “first” and “second” in the claims for clarity. In this case, the components designated using “first” and “second” in the claims indicate the “first” and “third” components in the present specification. This rule is applied not only to components but also other objects in a rational and flexible manner.

Certain embodiments of the present invention will be described below. Further, specific embodiments of the present invention will be described with reference to the accompanying drawings. Embodiments of the present invention are not limited to these specific embodiments. That is, the embodiments shown in the drawings are not the only embodiments for putting the present invention into practice. Sizes or positional relationships of members illustrated in each drawing may be exaggerated in order to facilitate understanding.

### Embodiment

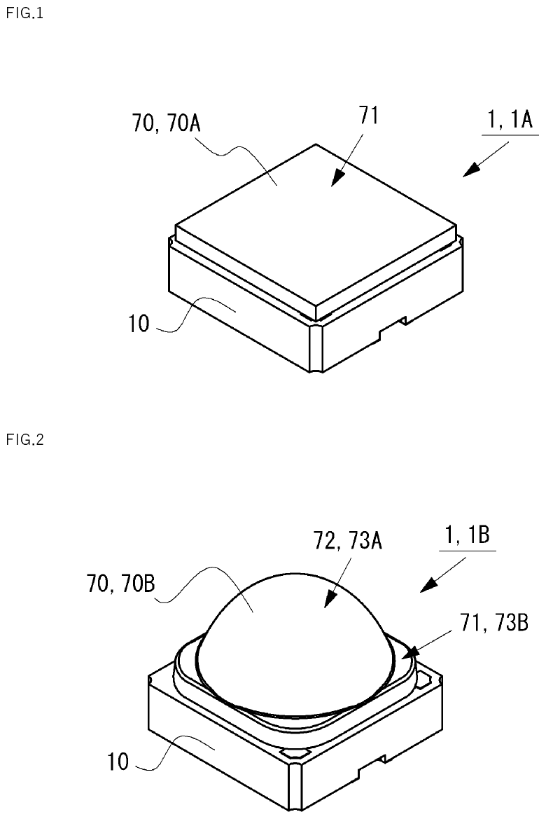

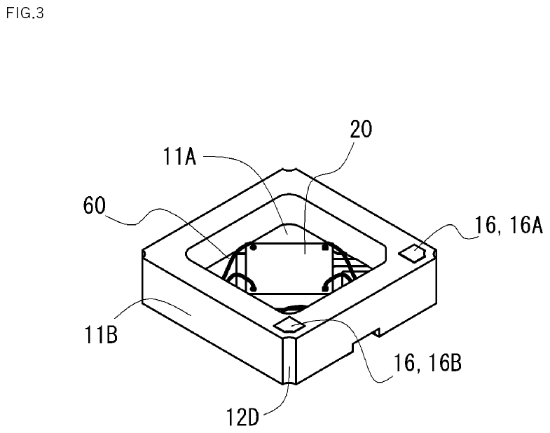

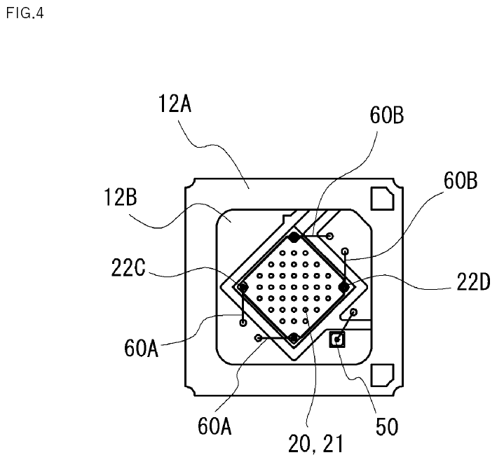

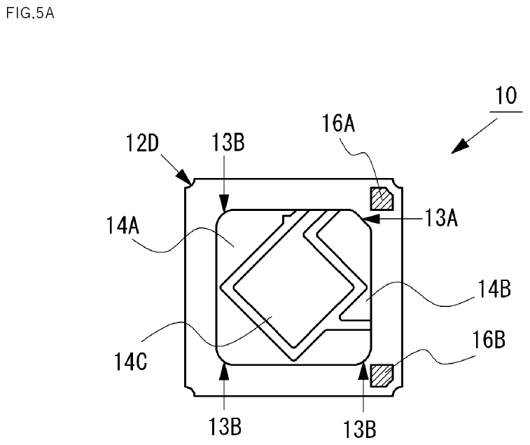

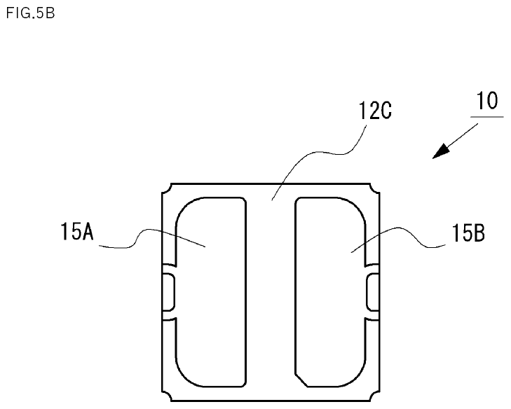

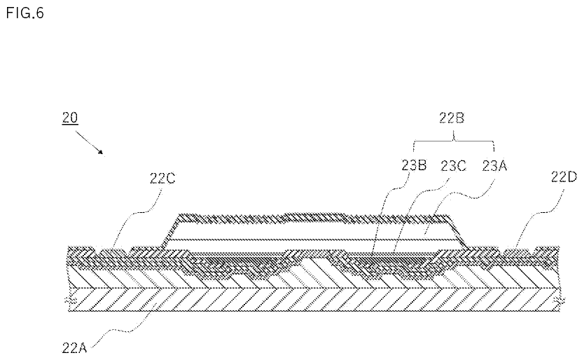

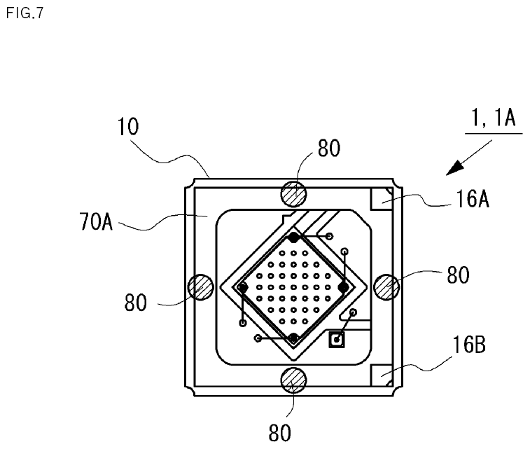

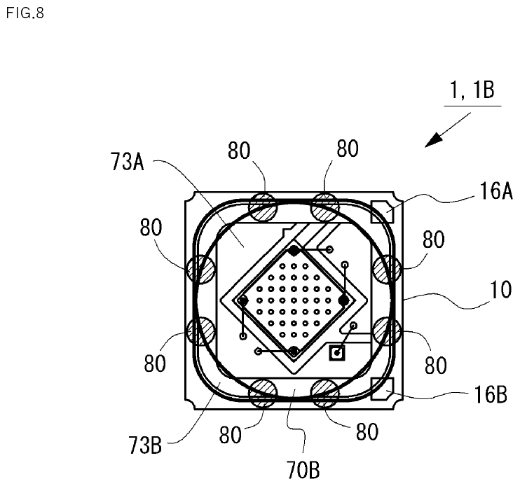

A light-emitting device 1 according to the embodiment is described. FIG. 1 to FIG. 8 are drawings for describing an illustrative form of the light-emitting device 1. FIG. 1 is a schematic perspective view of a light-emitting device 1A, which is an example of the light-emitting device 1. FIG. 2 is a schematic perspective view of a light-emitting device 1B, which is an example of the light-emitting device 1. FIG. 3 is a schematic perspective view of the light-emitting device 1 before a light-transmissive member 70 is mounted. FIG. 4 is a schematic top view showing the state shown in FIG. 3. FIG. 5A is a schematic top view of a base member 10. In FIG. 5A, electrode distinguishing marks 16 are indicated by hatching. FIG. 5B is a schematic bottom view of the base member 10. FIG. 6 is a schematic cross-sectional view illustrating an example of a light-emitting element 20. FIG. 7 is a schematic top view of the light-emitting device 1A. In FIG. 7, bonding members 80 are indicated by hatching. FIG. 8 is a schematic top view of the light-emitting device 1B. In FIG. 8, the bonding members 80 are indicated by hatching.

The light-emitting device 1 includes a plurality of components. The components include the base member 10, the light-emitting element 20, a protective element 50, a plurality of wirings 60, the light-transmissive member 70, and the bonding member 80.

The light-emitting device 1 may include other components. For example, the light-emitting device 1 may further include a light-emitting element such as a light-emitting diode and a semiconductor laser element in addition to the light-emitting element 20. The light-emitting device 1 does not necessarily include some of the components described above.

Each component will be first described below.

### Base Member 10

The base member 10 includes a base portion 11A and a lateral wall 11B. The base member 10 has a first surface 12B and a second surface 12C opposite to the first surface. The base portion 11A of the base member 10 has the first surface 12B. The lateral wall 11B defines a frame surrounding the first surface 12B in a top view. The lateral wall 11B of the base member 10 has an upper surface 12A. The inner periphery of the upper surface 12A has the shape of a frame surrounding the first surface 12B in a top view. Other components are disposed on the first surface 12B of the base member 10.

The outer shape of the base member 10 is rectangular in a top view. The outer shape of the base member 10 may not be rectangular in a top view. The shape of the frame defined of the lateral wall 11B is rectangular in a top view. The shape of the frame may not be rectangular in a top view. The angle defined by a side of the rectangular outer shape of the base member 10 and a side of the rectangular frame defined of the lateral wall 11B is within 15° in a top view. A side of the rectangular outer shape of the base member 10 is preferably parallel to a side of the rectangular frame defined of the lateral wall 11B in a top view. As used herein, the term “parallel” can include a difference of ±5°.

The rectangular outer shape of the base member 10 in a top view has a concave surface 12D extending from the upper surface 12A to the second surface 12C on at least any of the four corners of the rectangular shape. The concave surface 12D extending from the upper surface 12A to the second surface 12C can be formed at each of the four corners of the rectangular shape. All the concave surfaces formed at the four corners of the rectangular shape have the same shape.

The shape of at least one of the four corners of the rectangular frame of the lateral wall 11B surrounding the first surface 12B in a top view differs from the shape of the other three corners. By forming the shape different from the shape of the other three corners on at least one of the four corners of the frame, the orientation of the base member 10 can be identified in a top view. Hereinafter the corners are distinguished by referring the one of the four corners of the rectangular frame defined of the lateral wall 11B having a shape different from the shape of the other three corners to as a first corner 13A and referring the other three corners to as second corners 13B.

The distance from the center of the rectangular frame defined of the lateral wall 11B to the first corner 13A is shorter than the distance from this center to the second corner 13B in a top view. The first corner 13A satisfies this relationship in terms of distance with the three second corners 13B. The distance from the first corner 13A to the corner closest to the first corner 13A among the four corners of the rectangular outer shape of the base member 10 is longer than the distance from one second corner 13B to the corner closest to this second corner 13B among the four corners of the rectangular outer shape of the base member 10 in a top view. The first corner 13A satisfies this relationship in terms of distance with the three second corners 13B.

Main materials of the base portion 11A and the lateral wall 11B of the base member 10 are ceramics. The base portion 11A and the lateral wall 11B are integrally formed. Examples of the ceramics serving as the main materials of the base portion 11A and the lateral wall 11B include aluminum nitride, aluminum oxide, and mullite.

The term “main material” refers to a material constituting the largest proportion of an article to be obtained by weight or volume. In the case in which an article to be obtained is formed of a single material, that material serves as the main material. That is, the expression that a certain material is a main material also imply the case in which the proportion of the material can be 100%.

The base member 10 includes a first metal film 14A, a second metal film 14B, and a third metal film 14C. On the first surface 12B of the base member 10, the first metal film 14A, the second metal film 14B, and the third metal film 14C spaced apart from the first metal film 14A and the second metal film 14B in a top view are disposed. The third metal film 14C is spaced apart from the first metal film 14A and the second metal film 14B on the surface but may be connected to any of the metal films inside the base member 10.

The center of the rectangular outer shape of the base member 10 overlaps with the third metal film 14C in a top view. In a top view, the first metal film 14A is connected to three of the four corners of the rectangular frame defined of the lateral wall 11B, and the second metal film 14B is connected to the remaining one corner. Among the four corners of the rectangular frame, the corner connected to the second metal film 14B in a top view is the first corner 13A.

The third metal film 14C has a region having a rectangular shape (hereinafter referred to as a rectangular region) having at least one side of the outer periphery of the third metal film 14C in a top view. The rectangular region is a region overlapping with the center of the rectangular outer shape of the base member 10 in a top view. The rectangular region is surrounded by the first metal film 14A and the second metal film 14B in a top view.

The angle defined by an imaginary straight line connecting opposite angles of the rectangular shape of the rectangular region of the third metal film 14C and an imaginary straight line connecting opposite angles of the rectangular outer shape of the base member 10 is 40° or more and 50° or less in a top view.

The base member 10 includes a first electrode portion 15A and a second electrode portion 15B. The first electrode portion 15A and the second electrode portion 15B are provided on the second surface 12C. The second electrode portion 15B is spaced apart from the first electrode portion 15A.

The first metal film 14A is electrically connected to the first electrode portion 15A. The second metal film 14B is electrically connected to the second electrode portion 15B. The first metal film 14A and the second metal film 14B are electrically connected to the first electrode portion 15A and the second electrode portion 15B, respectively, through electroconductive members extending inside the base member 10. The first electrode portion 15A and the second electrode portion 15B are not provided on the outer lateral surfaces of the base member 10. The first electrode portion 15A and the second electrode portion 15B are not provided on the upper surface 12A of the base member 10.

The first electrode portion 15A and the second electrode portion 15B have different shapes in a plan view (hereinafter referred to as a bottom view) of the second surface 12C side as seen from a direction perpendicular to the second surface 12C. The second electrode portion 15B has a shape different from the shape of the first electrode portion 15A on the second surface 12C. By making the shapes of the two electrode portions different as described above, the first electrode portion 15A and the second electrode portion 15B can each be identified in a bottom view.

The base member 10 has the electrode distinguishing mark 16. The base member 10 has a plurality of the electrode distinguishing marks 16. Each electrode distinguishing mark 16 is provided on the upper surface 12A of the base member 10. On the upper surface 12A, each electrode distinguishing mark 16 is provided in the vicinity of an angle of the rectangular outer shape of the base member 10. The “corner” of the rectangular shape described above indicates the same portion as the “angle” of the rectangular shape described here. The same portion is referred to as a “corner” or an “angle” below as appropriate.

The plurality of the electrode distinguishing marks 16 include two electrode distinguishing marks 16 provided in the vicinities of two adjacent angles of the rectangular outer shape of the base member 10. These two electrode distinguishing marks 16 are respectively referred to as a first electrode distinguishing mark 16A and a second electrode distinguishing mark 16B to be distinguished.

Each electrode distinguishing mark 16 is provided in the vicinity of a corner of the rectangular frame defined of the lateral wall 11B. The base member 10 has an electrode distinguishing mark 16 provided in the vicinity of the first corner 13A. The base member 10 has the first electrode distinguishing mark 16A provided in the vicinity of the first corner 13A and the second electrode distinguishing mark 16B provided in the vicinity of the second corner 13B.

A portion of the outer periphery of the electrode distinguishing mark 16 has a shape contoured to the outer shape of the base member 10 in a top view. The portion of the outer periphery of the electrode distinguishing mark 16 has a concave shape contoured to the concave surface 12D of the base member 10 in a top view. By forming a shape contoured to the outer periphery, the electrode distinguishing mark 16 can be provided up to a position closer to the outer periphery. In the case in which another component is disposed on the upper surface 12A of the base member 10, such an arrangement that a portion of the electrode distinguishing mark 16 does not overlap with the component is facilitated, which allows the electrode distinguishing mark 16 to be distinguished easily.

The outer periphery of the electrode distinguishing mark 16 includes a first side parallel to a side of the rectangular outer shape of the base member 10, a second side perpendicular to the first side, and a third side connected to the first side and the second side and contoured to the concave surface 12D. The first side and the second side are sides along the two respective adjacent sides of the rectangular outer shape of the base member 10. The third side forms a curved line.

The electrode distinguishing mark 16 has a fourth side opposite to the third side and connected to the first side and a fifth side opposite to the third side and connected to the second side. The fourth side is parallel to the second side, and the fifth side is parallel to the first side. The fourth side and the fifth side are connected to each other.

The electrode distinguishing mark 16 does not extend from the vicinity of the angle of the rectangular outer shape of the base member 10 to the middle of the side of the rectangular shape. The electrode distinguishing mark 16 is provided such that 50% or more of the area of the electrode distinguishing mark 16 is within an angle region of the upper surface 12A of the base member 10. The electrode distinguishing mark 16 is desirably provided within the angle region of the upper surface 12A of the base member 10. Such an arrangement allows for allocating easily a bonding region used when another component is bonded to the upper surface 12A.

On the upper surface 12A, the angle region can be defined as a region including an angle of the rectangular outer shape of the base member 10 among regions formed by division by imaginary straight lines passing through the respective sides constituting the frame defined of the lateral wall 11B in a top view.

The electrode distinguishing marks 16 are not provided in the angle regions of all the four angles of the rectangular outer shape of the base member 10. The angle regions of the four angles include at least one angle region in which the electrode distinguishing mark is not provided. In the base member 10 shown in the drawings, among the angle regions of the four angles, the angle regions of two adjacent angles are each provided with an electrode distinguishing mark 16, and the angle regions of the two remaining adjacent angles are not provided with the electrode distinguishing mark 16.

### Light-Emitting Element 20

The light-emitting element 20 is an element that emits light. As for the light-emitting element 20, a main surface from which light emitted from the light-emitting element 20 is extracted is referred to as a light extraction surface 21. The light-emitting element 20 has an upper surface, a lower surface, and a plurality of lateral surfaces. The upper surface of the light-emitting element 20 serves as the light extraction surface 21. The outer shape of the light-emitting element 20 is rectangular in a top view. The outer shape of the light-emitting element 20 in a top view may not be rectangular.

For example, the light-emitting element 20 emits ultraviolet light. The light-emitting element 20 preferably emits light with a peak emission wavelength within the range of 350 nm or more and 410 nm or less. The upper limit of the wavelength of the ultraviolet light is defined as 400 nm in some cases, but in the present application, light within the range of 400 nm or more and 410 nm or less is also included in the ultraviolet light.

An upper surface electrode is provided on the upper surface of the light-emitting element 20. The upper surface of the light-emitting element 20 is provided with a first upper surface electrode as a first electrode 22C and a second upper surface electrode as a second electrode 22D of the light-emitting element 20.

The light-emitting element 20 includes a supporting substrate 22A and a semiconductor layered body 22B disposed on the supporting substrate 22A. The semiconductor layered body 22B includes a first electroconductive semiconductor layer 23A, a second electroconductive semiconductor layer 23B, and an active layer 23C. For example, the first electroconductive semiconductor layer 23A is an n-side semiconductor layer. For example, the second electroconductive semiconductor layer 23B is a p-side semiconductor layer.

In the light-emitting element 20, the first electroconductive semiconductor layer 23A, the active layer 23C, and the second electroconductive semiconductor layer 23B are layered in order on the supporting substrate 22A side. The supporting substrate 22A of the light-emitting element 20 is not a sapphire substrate. For example, the supporting substrate 22A is a silicon substrate.

In the manufacturing of the light-emitting element 20, an underlayer including a GaN layer is grown on a sapphire substrate, and the first electroconductive semiconductor layer, the active layer, and the second electroconductive semiconductor layer are epitaxially grown in order on the underlayer. After that, the semiconductor layered body is bonded to the supporting substrate, and the underlayer and the sapphire substrate are removed. At this time, for example, the underlayer and the sapphire substrate can be removed by irradiating the underlayer with laser light.

In the case in which a light-emitting element that emits ultraviolet light with a peak emission wavelength of 350 nm or more and 410 nm or less is manufactured, the sapphire substrate can be removed in this manner by using the underlayer including the GaN layer. The light extraction efficiency is better in the case in which light is directly emitted without the sapphire substrate than with the sapphire substrate. By bonding the semiconductor layered body to the supporting substrate and removing the sapphire substrate, the first electroconductive semiconductor layer can be provided on the light extraction surface side, and the first upper surface electrode and the second upper surface electrode can be provided on the light extraction surface side.

The case in which a light-emitting element that emits ultraviolet light with a peak emission wavelength of 350 nm or more and 410 nm or less is manufactured and the case in which a light-emitting element that emits ultraviolet light with a peak emission wavelength of 330 nm or less is manufactured have a difference in that whether an underlayer not including an AlN layer is used or an underlayer including an AlN layer is used. This is because the ratio of Al when an AlGaN layer is grown can be adjusted according to the peak emission wavelength. The case of ultraviolet light of 330 nm or less employs a ratio of Al greater than the case of ultraviolet light of 350 nm or more and 410 nm or less and preferably uses an underlayer including an AlN layer.

Accordingly, although an underlayer including an AlN layer may be used in the case in which a light-emitting element that emits ultraviolet light with a peak emission wavelength of 330 nm or less is manufactured, laser light absorbed in the case of GaN is not absorbed by AlN in this case, and it may be impossible to remove the sapphire substrate by the same method.

The light-emitting element 20 emits ultraviolet light with a peak emission wavelength within the wavelength range of 350 nm or more and 410 nm or less. The light extraction efficiency can be enhanced by selecting a light-emitting element 20 with a wavelength within such a wavelength range of ultraviolet light and employing a light-emitting element 20 in which a sapphire substrate does not exist over the light extraction surface. A light-emitting element 20 in which the n-side semiconductor layer serves as the light extraction surface can be employed.

### Protective Element 50

The protective element 50 prevents an excessive current from flowing through and breaking a specific element (such as the light-emitting element 20). Examples of the protective element 50 include a Zener diode. A Zener diode formed of Si can be employed as the Zener diode.

### Wiring 60

The wiring 60 is a linear electroconductive material including bonding portions at both ends. The bonding portions at both ends are portions bonded to other components. For example, the wiring 60 is a metal wire. Examples of the metal to be used include gold, aluminum, silver, and copper.

### Light-Transmissive Member 70

The light-transmissive member 70 has an upper surface 71, a lower surface, and a lateral surface. The upper surface 71 of the light-transmissive member 70 is a flat surface. The lower surface of the light-transmissive member 70 is a flat surface. The light-transmissive member 70 has an optical effect such as reflection, transmission, and refraction or optical action such as condensing, diffusion, and collimation on incident light. For example, the light-transmissive member 70 can be formed of borosilicate glass, sapphire, or the like.

For example, a light-transmissive member 70A having the shape of a flat plate can be employed for the light-transmissive member 70. For example, a light-transmissive member 70B having a lens surface 72 can be employed for the light-transmissive member 70.

The light-transmissive member 70B having the lens surface 72 will be further described. The light-transmissive member 70B can be said to be a lens member. The light-transmissive member 70B has the lens surface 72 on the upper surface 71 side. The upper surface 71 of the light-transmissive member 70B is provided outside the lens surface 72 in a top view.

The portion of the light-transmissive member 70B overlapping with the lens surface 72 in a top view is referred to as a lens portion 73A. The portion of the light-transmissive member 70B overlapping with the upper surface 71 in a top view is referred to as a non-lens portion 73B. The lens portion 73A has the lens surface 72, and the non-lens portion 73B is provided outside the lens portion 73A in a top view.

The outer shape of the light-transmissive member 70B is rectangular in a top view. The outer shape of the lens portion 73A is circular or elliptic, and the outer shape of the non-lens portion 73B is rectangular in a top view. The outer shape of the non-lens portion 73B is the outer shape of the light-transmissive member 70B in a top view.

The distance between the outer periphery of the lens portion 73A and the outer periphery of the non-lens portion 73B at an angle of the rectangular outer shape of the light-transmissive member 70B is longer than the distance between the outer periphery of the lens portion 73A and the outer periphery of the non-lens portion 73B at the middle of a side of the rectangular outer shape in a top view. With such a shape, the light-transmissive member 70B in which the lens surface 72 is large can be employed while the size of the outer shape of the light-emitting device 1 is kept small.

The light-transmissive member 70B has a rectangular outer shape with four rounded corners in a top view. The four rounded corners are formed on the non-lens portion 73B. Rounding the four corners allows for reducing the ratio of the region occupied by the non-lens portion 73B in the light-transmissive member 70B in a top view, and the light-transmissive member 70B in which the lens surface 72 is large can be formed.

### Bonding Member 80

The bonding member 80 are a bonding material in a hardened state. The bonding material is used to bond different components, and the bonding material is hardened to form the bonding member 80. For the bonding material, for example, a resin adhesive can be used. For the resin adhesive, for example, a thermosetting resin that is cured by application of heat can be used. Alternatively, for example, a UV-curable resin that is cured by application of ultraviolet light may be used.

Subsequently, the light-emitting device 1 including the components described above will be described.

### Light-Emitting Device 1

In the light-emitting device 1, the light-emitting element 20 is disposed on the first surface 12B of the base member 10. The light-emitting element 20 is disposed on the third metal film 14C. The light-emitting element 20 is disposed in the rectangular region of the third metal film 14C. The light-emitting element 20 is disposed on the base member 10 with the four corners of the rectangular outer shape of the light-emitting element 20 aligned with the four corners of the rectangular shape of the rectangular region in a top view. The angle defined by an imaginary straight line connecting opposite angles of the rectangular outer shape of the base member 10 and an imaginary straight line connecting opposite angles of the rectangular outer shape of the light-emitting element 20 is 40° or more and 50° or less in a top view.

In the light-emitting device 1, the wiring 60 is bonded to the light-emitting element 20. The light-emitting device 1 includes one or a plurality of first wirings 60A bonded to the first electrode 22C of the light-emitting element 20 and one or a plurality of second wirings 60B bonded to the second electrode 22D of the light-emitting element 20. Each first wiring 60A is further bonded to the first metal film 14A. Each second wiring 60B is further bonded to the second metal film 14B. Anode potential is applied to one of the first electrode portion 15A and the second electrode portion 15B, and cathode potential is applied to the other.

The light-emitting device 1 can employ a light-emitting element 20 that emits ultraviolet light with a peak emission wavelength of 350 nm or more and 410 nm or less. This light-emitting element 20 is a light-emitting element in which a sapphire substrate does not exist over the light extraction surface 21. In this light-emitting element 20, the n-side semiconductor layer serves as the light extraction surface, and the first electrode 22C and the second electrode 22D are disposed on the light extraction surface 21 side.

Each first wiring 60A is bonded to the first metal film 14A inside a region surrounded by an imaginary straight line passing through a first side, which is one of the four sides of the rectangular outer shape of the light-emitting element 20, and the rectangular frame defined of the lateral wall 11B of the base member 10, the region not containing the center of the light extraction surface 21 of the light-emitting element 20. The portion of the rectangular frame defined of the lateral wall 11B defining the region includes the first corner 13A.

Each second wiring 60B is bonded to the second metal film 14B inside a region surrounded by an imaginary straight line passing through a second side, which is the side opposite to the first side among the four sides of the rectangular outer shape of the light-emitting element 20, and the rectangular frame defined of the lateral wall 11B of the base member 10, the region not containing the center of the light extraction surface 21 of the light-emitting element 20. The portion of the rectangular frame defined of the lateral wall 11B defining this region includes the second corner 13B. This second corner 13B may be a corner located diagonally to the first corner 13A.

In the light-emitting device 1, the protective element 50 is disposed on the first surface 12B of the base member 10. The protective element 50 is disposed on the first metal film 14A. The protective element 50 protects the light-emitting element 20.

In the light-emitting device 1, the light-transmissive member 70 is disposed over the base member 10. The light-transmissive member 70 covers the first surface 12B of the base member 10 in a top view. The light-transmissive member 70 is bonded to the upper surface 12A of the base member 10. By bonding the light-transmissive member 70 to the base member 10, a closed space surrounded by the base member 10 and the light-transmissive member 70 is formed. This closed space may be a hermetically sealed space.

A portion of the light-transmissive member 70 overlaps with at least a portion of the electrode distinguishing mark 16 in a top view. The light-transmissive member 70 overlaps with at least a portion of the electrode distinguishing mark 16 in this manner, which allows for miniaturizing the light-emitting device 1. A portion of the light-transmissive member 70 overlaps with at least a portion of each of the first electrode distinguishing mark 16A and the second electrode distinguishing mark 16B in a top view.

The light-transmissive member 70 is bonded to the base member 10 with the bonding material. The bonding member 80 is disposed between the upper surface 12A of the base member 10 and the lower surface of the light-transmissive member 70. The bonding member 80 bond the base member 10 and the light-transmissive member 70 together.

On the upper surface 12A of the base member 10, the bonding member 80 is not disposed at least in the regions in which the first electrode distinguishing mark 16A and the second electrode distinguishing mark 16B are provided. That is, on the upper surface 12A, the bonding member 80 is not disposed in the vicinities of the two adjacent angles of the rectangular outer shape of the base member 10 near which the first electrode distinguishing mark 16A and the second electrode distinguishing mark 16B are respectively provided.

By disposing the bonding member 80 so as not to overlap with the electrode distinguishing mark 16, the bonding member 80 can be prevented from hindering distinction of the electrode distinguishing mark 16. By disposing the electrode distinguishing mark 16 in the vicinity of the angle of the rectangular outer shape of the base member 10, the bonding member 80 is allowed to be formed not in the vicinity of the angle but, for example, in the vicinity of the middle of side.

The longer the distance from the center of the rectangular outer shape of the base member 10 to the inner periphery of the upper surface 12A is in a top view, the smaller the angle of light traveling from the center of the light-emitting element 20 toward the inner periphery of the upper surface 12A with respect to the upper surface 12A is. The smaller this angle is, the longer the optical path length from the upper surface 12A of the base member 10 to the lower surface of the light-transmissive member 70 is. The bonding members 80 are not disposed at locations that make the optical path length comparatively long but are disposed at locations that make the optical path length short on the upper surface 12A of the base member 10, so that the amount of light emitted from the light-emitting element 20 and incident on the bonding members 80 can be reduced.

The bonding member 80 is preferably disposed between the upper surface 12A of the base member 10 and the lower surface of the light-transmissive member 70 at position not in contact with the electrode distinguishing mark 16. Contact between the bonding member 80 and the electrode distinguishing mark 16 can affect the bonding balance, and preventing the contact can stabilize the bonding.

FIG. 1 and FIG. 7 schematically show the light-emitting device 1 in the case in which the light-transmissive member 70A having the shape of a flat plate is employed as the light-transmissive member 70, and FIG. 2 and FIG. 8 schematically show the light-emitting device 1 in the case in which the light-transmissive member 70B having the lens surface 72 is employed as the light-transmissive member 70. For convenience, the light-emitting device 1 employing the light-transmissive member 70A is referred to as the light-emitting device 1A, and the light-emitting device 1 employing the light-transmissive member 70B is referred to as the light-emitting device 1B to distinguish the devices using different reference numerals.

In the light-emitting device 1A, entirety of the electrode distinguishing mark 16 overlap with the light-transmissive member 70A in a top view. Further, the entirety of each electrode distinguishing mark 16 overlaps with the light-transmissive member 70A in a top view. The electrode distinguishing mark 16 may not overlap with the light-transmissive member 70A entirely.

In the case in which the light-transmissive member 70A having the shape of a flat plate is employed, the light-transmissive member 70A having a rectangular shape whose angles are not rounded in a top view is easy to manufacture. If a process of rounding the angles is performed, manufacturing steps increase correspondingly, leading to a decrease in productivity and an increase in production cost.

Accordingly, the light-transmissive member 70A has a rectangular shape having angles that are not rounded in a top view, and the larger the area overlapping with the upper surface 12A of the base member 10 is, the further the bonding to the base member 10 can be stabilized. The electrode distinguishing mark 16 can therefore overlap with the light-transmissive member 70A entirely.

The electrode distinguishing mark 16 is provided near the outer shape of the base member 10, and a portion of the outer periphery of the electrode distinguishing mark 16 may overlap with a portion of the outer periphery of the light-transmissive member 70A in a top view to invite error in distinction of the electrode distinguishing mark 16. By providing the first corner 13A in the frame defined of the lateral wall 11B of the base member 10, the orientation of the base member 10 can be identified using the first corner 13A, and the electrodes can be distinguished. In consideration of stabilization of the bonding, there is a high probability that the outer periphery of the light-transmissive member 70A does not overlap with the frame defined of the lateral wall 11B, and the first corner 13A can be effectively used for distinction of the electrodes.

In the light-emitting device 1A, the bonding members 80 are formed in the vicinities of the middles of the respective sides of the rectangular outer shape of the base member 10. Each bonding member 80 is not disposed in the vicinities of the four corners of the rectangular outer shape of the base member 10 and is not disposed in the vicinities of the four corners of the frame defined of the lateral wall 11B. This arrangement facilitates use of the first corner 13A for distinction of the electrodes.

In the light-emitting device 1B, a portion of the electrode distinguishing mark 16 does not overlap with the light-transmissive member 70B in a top view. By preventing a portion of the electrode distinguishing mark 16 from overlapping with the light-transmissive member 70B, the electrode distinguishing mark 16 is easily distinguished without being hindered by the light-transmissive member 70B. A portion of the electrode distinguishing mark 16 overlaps with the non-lens portion 73B in a top view. Entirety of the electrode distinguishing mark 16 do not overlap with the lens portion 73A of the light-transmissive member 70B in a top view. This can apply to every electrode distinguishing mark 16 in the light-emitting device 1B.

A portion of the lens portion 73A overlaps with the upper surface 12A of the base member 10 in a top view. The outer periphery of the lens portion 73A includes a portion overlapping with the upper surface 12A of the base member 10 and a portion overlapping with the first surface 12B of the base member 10 in a top view. The outer periphery of the lens portion 73A overlaps with the first surface 12B in the vicinities of the second corners 13B of the frame defined of the lateral wall 11B in a top view. The first corner 13A is located inward of the outer periphery of the lens portion 73A in a top view.

In the light-emitting device 1B, the outer periphery of the lens portion 73A passes through the vicinities of or directly above the four corners of the frame defined of the lateral wall 11B in a top view. Alternatively, the four corners of the frame may be located inward of the outer periphery of the lens portion 73A in a top view. When a lens surface 72 is larger, the probability that such a condition develops becomes high, and in this case, errors may be easily invited when the first corner 13A of the frame is to be distinguished. The distinguishability of the electrodes can be improved by providing the electrode distinguishing mark 16 on the upper surface 12A of the base member 10 so as to at least partially protrude from the light-transmissive member 70B.

A portion of the outer periphery of the electrode distinguishing mark 16 having the shape contoured to the outer shape of the base member 10 does not overlap with the light-transmissive member 70B in a top view. By forming the electrode distinguishing mark 16 contoured to the outer shape up to the vicinity of the outer shape, the portion not overlapping with the light-transmissive member 70B is more certainly provided, and distinguishability is improved. This can apply to every electrode distinguishing mark 16 in the light-emitting device 1B.

The third side constituting the outer periphery of the electrode distinguishing mark 16 does not overlap with the light-transmissive member 70B in a top view. The first side and the second side constituting the outer periphery of the electrode distinguishing mark 16 do not overlap with the light-transmissive member 70B in a top view. A portion of the fourth side and a portion of the fifth side constituting the outer periphery of the electrode distinguishing mark 16 do not overlap with the light-transmissive member 70B in a top view. The other portion of the fourth side and the other portion of the fifth side constituting the outer periphery of the electrode distinguishing mark 16 overlap with the light-transmissive member 70B in a top view. This can apply to every electrode distinguishing mark 16 in the light-emitting device 1B.

As for the light-transmissive member 70B, the distance between the outer periphery of the lens portion 73A and the outer periphery of the non-lens portion 73B in the vicinity of an angle of the rectangular outer shape of the base member 10 is longer than the distance between the outer periphery of the lens portion 73A and the outer periphery of the non-lens portion 73B in the vicinity of the middle of a side of the rectangular outer shape of the base member 10 in a top view. With such an arrangement of the light-transmissive member 70B, the non-lens portion 73B is easily arranged in the region of the light-transmissive member 70B overlapping with the electrode distinguishing mark 16 in a top view. The light-transmissive member 70B less hinders distinction of the electrode distinguishing mark 16 in the case in which the non-lens portion 73B overlaps with the electrode distinguishing mark 16 than in the case in which the lens portion 73A overlaps with the electrode distinguishing mark 16.

The portion of the outer shape of the light-transmissive member 70B with a rounded corner passes on the electrode distinguishing mark 16 in a top view. Rounding the four corners of the shape of the light-transmissive member 70B facilitates providing of the portion of the electrode distinguishing mark 16 not overlapping with the light-transmissive member 70B. With this arrangement, the distinguishability of the electrode distinguishing marks 16 can be improved. This can apply to every electrode distinguishing mark 16 in the light-emitting device 1B.

The portion of the outer shape of the light-transmissive member 70B with a rounded corner in a top view passes through the fourth side and the fifth side of the outer periphery of the electrode distinguishing mark 16. The area of the portion of the electrode distinguishing mark 16 overlapping with the light-transmissive member 70B is preferably smaller than the area of the portion not overlapping with the light-transmissive member 70B in a top view. Such a design allows for increasing the certainty that the portions of both the first electrode distinguishing mark 16A and the second electrode distinguishing mark 16B protrude from the light-transmissive member 70B even with misalignment in mounting.

In a direction perpendicular to a side of the rectangular outer shape of the base member 10, the maximum distance from the outer periphery of the electrode distinguishing mark 16 not overlapping with the light-transmissive member 70B to the outer periphery of the light-transmissive member 70B is longer than the distance from the middle of this side to the light-transmissive member 70B. In a direction perpendicular to a side adjacent to that side, the maximum distance from the outer periphery of the electrode distinguishing mark 16 not overlapping with the light-transmissive member 70B to the outer periphery of the light-transmissive member 70B is longer than the distance from the middle of this side to the light-transmissive member 70B. This arrangement allows a portion of the electrode distinguishing mark 16 to protrude from the light-transmissive member 70B even in the case in which the outer periphery of the light-transmissive member 70B overlaps with the outer periphery of the base member 10 in a top view due to misalignment in mounting.

In the light-emitting device 1B, as for each side of the rectangular outer shape of the base member 10, the bonding members 80 are formed at positions the same distance away from the vicinity of the middle of the side. Each bonding member 80 is not disposed in the vicinities of the four corners of the rectangular outer shape of the base member 10, but some of the bonding members 80 can be disposed in the vicinities of the four corners of the frame defined of the lateral wall 11B. It is easy to use the electrode distinguishing marks 16 for distinguishing the electrodes in the light-emitting device 1B, and the first corner 13A is not required for distinction of the electrodes, so that the bonding members 80 may be brought into the vicinities of the four corners of the frame defined of the lateral wall 11B. A larger number of bonding members 80 are disposed in the light-emitting device 1B than in the light-emitting device 1A, which can also stabilize the bonding of the light-transmissive member 70B having a lens shape.

While certain embodiment of the present invention has been described above, the light-emitting device according to the present invention is not strictly limited to the embodiment above. That is, the present invention can be achieved without being limited to the external shape and the structure of the light-emitting device in the embodiment described above. It is also not required that all of the components of the described embodiment of the present invention be provided. For example, in the case in which part of components of the light-emitting device disclosed in the embodiment is not disclosed in the claims, design flexibility such as substitution, omission, deformation, and changes in materials of the part of components by a person skilled in the art is permitted, and application of the invention described in the claims is specified.

The light-emitting devices disclosed as the embodiment can be used for a device that performs a process such as exposure to light, hardening of a paint, and hardening of an ink.

1. A light-emitting device, comprising:
a light-emitting element;
a base member having a rectangular outer shape in a top view and having a first surface, wherein the light-emitting element is disposed at the first surface, a second surface opposite to the first surface, a lateral wall defining a frame surrounding the first surface in the top view, and an upper surface of the lateral wall;
a light-transmissive member disposed over the base member to cover the first surface in the top view; and
a bonding member disposed between a lower surface of the light-transmissive member and the upper surface of the lateral wall to bond the base member and the light-transmissive member together,
wherein the base member includes a first electrode portion on the second surface, a second electrode portion spaced apart from the first electrode portion, and electrode distinguishing marks respectively provided in vicinities of two adjacent angles of the rectangular outer shape on the upper surface,
wherein a portion of the light-transmissive member overlaps with at least a portion of each of the electrode distinguishing marks in the top view, and
wherein the bonding member is not disposed at least in the vicinities of the two adjacent angles on the upper surface.

2. The light-emitting device according to claim 1, further comprising:
one or more first wirings bonded to a first electrode of the light-emitting element; and
one or more second wirings bonded to a second electrode of the light-emitting element,
wherein the light-emitting element has a rectangular outer shape in the top view,
wherein on the first surface of the base member is disposed a first metal film electrically connected to the first electrode portion, a second metal film electrically connected to the second electrode portion, and a third metal film spaced apart from the first metal film and the second metal film in the top view,
wherein an angle defined by an imaginary straight line connecting opposite angles of the rectangular outer shape of the base member and an imaginary straight line connecting opposite angles of the rectangular outer shape of the light-emitting element is 40° or more and 50° or less in the top view,
wherein each of the one or more first wirings is bonded to the first metal film inside a region surrounded by an imaginary straight line passing through a first side serving as one of four sides of the rectangular outer shape of the light-emitting element and the frame having a rectangular shape formed of the lateral wall of the base member, the region not comprising a center of a light extraction surface of the light-emitting element, and
wherein each of the one or more second wirings is bonded to the second metal film inside a region surrounded by an imaginary straight line passing through a second side opposite to the first side among the four sides of the rectangular outer shape of the light-emitting element and the frame having the rectangular shape formed of the lateral wall of the base member, the region not comprising the center of the light extraction surface of the light-emitting element.

3. The light-emitting device according to claim 2, wherein the light-emitting element comprises an n-side semiconductor layer serving as the light extraction surface and no sapphire substrate over the n-side semiconductor layer and having a peak emission wavelength within a wavelength range of 350 nm or more and 410 nm or less.

4. The light-emitting device according to claim 1,
wherein the light-transmissive member comprises a lens member comprising a lens portion having a lens surface on an upper surface side and a non-lens portion outside the lens portion,
wherein a distance between an outer periphery of the lens portion and an outer periphery of the non-lens portion in a vicinity of an angle of the rectangular outer shape of the base member is longer than a distance between the outer periphery of the lens portion and the outer periphery of the non-lens portion in a vicinity of a middle of a side of the rectangular outer shape of the base member in the top view,
wherein a portion of the lens portion overlaps with the upper surface in the top view,
wherein at least one of the electrode distinguishing marks has a portion that does not overlap with the lens member in the top view, and
wherein entirety of the at least one of the electrode distinguishing marks does not overlap with the lens portion of the lens member in the top view.

5. The light-emitting device according to claim 4,
wherein the lens member has a rectangular outer shape with four rounded corners in the top view, and
wherein a rounded portion of the lens member passes over at least one of the electrode distinguishing marks in the top view.

6. The light-emitting device according to claim 4, wherein the bonding member is disposed between the upper surface of the base member and the lower surface of the light-transmissive member at a position not in contact with the electrode distinguishing marks.

7. The light-emitting device according to claim 1, wherein, as for the base member, a shape of at least one of four corners of the frame having a rectangular shape surrounding the first surface in the top view differs from a shape of the other three corners.

8. The light-emitting device according to claim 7,
wherein the light-transmissive member has a shape of a flat plate, and
wherein entirety of the electrode distinguishing marks overlap with the light-transmissive member in the top view.

9. The light-emitting device according to claim 7,
wherein the light-transmissive member comprises a lens member comprising a lens portion having a lens surface on an upper surface side and a non-lens portion outside the lens portion, and
wherein the one corner having the shape different from the shape of the other three corners is located inside an outer periphery of the lens portion in the top view.

10. The light-emitting device according to claim 4, wherein a portion of an outer periphery of the electrode distinguishing marks is contoured to the outer shape of the base member and does not overlap with the lens member in the top view.

11. The light-emitting device according to claim 10,
wherein each of four corners of the rectangular outer shape of the base member has a concave surface extending from the upper surface of the lateral wall to the second surface, and
wherein a portion of the outer periphery of the electrode distinguishing mark has a concave shape contoured to the concave surface in the top view.

12. The light-emitting device according to claim 1, wherein the second electrode portion has a shape different from a shape of the first electrode portion on the second surface.

13. The light-emitting device according to claim 1,
wherein the light-transmissive member comprises a lens member comprising a lens portion having a lens surface on an upper surface side and a non-lens portion outside the lens portion,
wherein a distance between an outer periphery of the lens portion and an outer periphery of the non-lens portion in a vicinity of an angle of the rectangular outer shape of the base member is longer than a distance between the outer periphery of the lens portion and the outer periphery of the non-lens portion in a vicinity of a middle of a side of the rectangular outer shape of the base member in the top view,
wherein a portion of the lens portion overlaps with the upper surface in the top view,
wherein each of the electrode distinguishing marks has a portion that does not overlap with the lens member in the top view, and
wherein entirety of each of the electrode distinguishing marks does not overlap with the lens portion of the lens member in the top view.
